(19) United States
(12) Patent Application Publication
(10) Pub. No.: US 2026/0363063 A1
(43) Pub. Date: Nov. 12, 2026

(54) ADAPTIVE THERMAL MANAGEMENT SYSTEM FOR THREE-DIMENSIONAL INTEGRATED CIRCUITS

(71) Applicant: International Business Machines Corporation, Armonk, NY (US)

(72) Inventors: Heather Nicole POLGREAN, Lagrangeville, NY (US); Jessica NAHULAN, Vaughan (CA); Tiberiu SUTO, Franklin, NY (US); Jeremy R. FOX, Georgetown, TX (US)

(21) Appl. No.: 19/205,120

(22) Filed: May 12, 2025

(51) Int. Cl. H10W 40/00; G06F 30/31; H10D 88/00

(52) U.S. Cl. CPC H10W 40/00; G06F 30/31; H10D 88/00

(57) ABSTRACT

In some implementations, a thermal management system may include a four-dimensional (4D)-printed thermally adaptive structure configured to change a shape, an alignment, or a configuration in response to a thermal profile and workload data associated with a three-dimensional (3D) integrated circuit. The thermal management system may include one or more sensors configured to provide real-time sensor data associated with the 3D integrated circuit. The thermal management system may include a controller configured to adjust thermal pathways of the 3D integrated circuit using cooling elements, the 4D-printed thermally adaptive structure, and thermal routing layers, and redistribute heat in the 3D integrated circuit in real-time based on the real-time sensor data.

### BACKGROUND

Thermal management in electronics involves various techniques related to heat generation by electronic components. Electronics encompass a wide range of components, including integrated circuits that come in a variety of forms.

### SUMMARY

Some aspects described herein relate to a method for providing thermal management of a three-dimensional (3D) integrated circuit. The method may include changing a shape, an alignment, or a configuration of a four-dimensional (4D)-printed thermally adaptive structure in response to a thermal profile and workload data associated with the 3D integrated circuit. The method may include receiving real-time sensor data associated with the 3D integrated circuit, and adjusting thermal pathways of the 3D integrated circuit using cooling elements, the 4D-printed thermally adaptive structure, and thermal routing layers. The method may include redistributing heat in the 3D integrated circuit in real-time based on the real-time sensor data.

Some aspects described herein relate to a thermal management system for a 3D integrated circuit. The thermal management system may include a 4D-printed thermally adaptive structure configured to change a shape, an alignment, or a configuration in response to a thermal profile and workload data associated with the 3D integrated circuit. The thermal management system may include one or more sensors configured to provide real-time sensor data associated with the 3D integrated circuit. The thermal management system may include a controller configured to adjust thermal pathways of the 3D integrated circuit using cooling elements, the 4D-printed thermally adaptive structure, and thermal routing layers, and redistribute heat in the 3D integrated circuit in real-time based on the real-time sensor data.

Some aspects described herein relate to a 3D integrated circuit. The 3D integrated circuit may include a logic core layer, a memory layer, a power management layer, and a thermal management system. The thermal management system may include a 4D-printed thermally adaptive structure configured to change a shape, an alignment, or a configuration in response to a thermal profile and workload data associated with the 3D integrated circuit. The thermal management system may include one or more sensors configured to provide real-time sensor data associated with the 3D integrated circuit. The thermal management system may include a controller configured to adjust thermal pathways of the 3D integrated circuit using cooling elements, the 4D-printed thermally adaptive structure, and thermal routing layers, and redistribute heat in the 3D integrated circuit in real-time based on the real-time sensor data.

### BRIEF DESCRIPTION OF THE DRAWINGS

FIG. 1 is a diagram of an example computing environment with devices capable of utilizing an adaptive thermal management system, as described herein.

FIGS. 2A-2C are diagrams of an example associated with providing an adaptive thermal management system for three-dimensional (3D) integrated circuits.

FIGS. 3A-3G are diagrams of example functions capable of being performed by a four-dimensional (4D)-printed thermally adaptive structure of the thermal management system.

FIGS. 4A-4D are diagrams of example functions capable of being performed by a controller of the thermal management system.

FIGS. 5 is a flowchart of an example process associated with providing an adaptive thermal management system for 3D integrated circuits.

### DETAILED DESCRIPTION

The following detailed description of example implementations refers to the accompanying drawings. The same reference numbers in different drawings may identify the same or similar elements.

Thermal management in a 3D integrated circuit is a significant challenge due to the high power density and localized hotspots that can lead to reduced performance, increased energy consumption, and decreased lifespan of the 3D integrated circuit. Existing thermal management solutions are largely static, failing to adapt to the dynamic and localized nature of heat generation in densely packed circuits. Moreover, these solutions often rely on expensive and energy-intensive external cooling systems, adding to the overall cost and environmental impact of the 3D integrated circuit. Over time, aging and usage patterns can further alter the thermal requirements of the 3D integrated circuit, reducing the efficiency of static solutions and necessitating a more responsive approach to thermal management. The increasing demand for high-performance computing, compact electronics, and reliable devices in various industries, including aerospace, automotive, and consumer electronics, further emphasizes the need to address the technical challenges associated with heat dissipation in 3D integrated circuits. Thus, current thermal management solutions consume computing resources (e.g., processing resources, memory resources, communication resources, and/or the like), networking resources, and/or the like associated with failing to adapt to the dynamic and localized nature of heat generation in a 3D integrated circuit, relying on expensive and energy-intensive external cooling systems for the 3D integrated circuit, failing to adapt to changing thermal requirements of the 3D integrated circuit, and/or the like.

Some implementations described herein provide an adaptive thermal management system for 3D integrated circuits. For example, a thermal management system may include a four-dimensional (4D)-printed thermally adaptive structure configured to change a shape, an alignment, or a configuration in response to a thermal profile and workload data associated with a three-dimensional (3D) integrated circuit. The thermal management system may include one or more sensors configured to provide real-time sensor data associated with the 3D integrated circuit. The thermal management system may include a controller configured to adjust thermal pathways of the 3D integrated circuit using cooling elements, the 4D-printed thermally adaptive structure, and thermal routing layers, and redistribute heat in the 3D integrated circuit in real-time based on the real-time sensor data.

In this way, an adaptive thermal management system is provided for 3D integrated circuits. For example, the thermal management system may optimize thermal management in a 3D integrated circuit by reducing the thermal resistance of the 3D integrated circuit. The thermal management system may maximize power consumption efficiency and may conserve energy sources. By efficiently dissipating heat in real-time, the thermal management system may reduce thermal stress and heat-induced noise, thus extending the lifespan and reliability of the 3D integrated circuit. Thus, the adaptive thermal management system conserves computing resources, networking resources, and/or the like that would otherwise have been consumed by failing to adapt to the dynamic and localized nature of heat generation in a 3D integrated circuit, relying on expensive and energy-intensive external cooling systems for the 3D integrated circuit, failing to adapt to changing thermal requirements of the 3D integrated circuit, and/or the like.

In some implementations, the thermal management system described herein may be utilized with high-performance computing (e.g., to provide enhanced cooling for graphics processing units (GPUs), central processing units (CPUs), and/or artificial intelligence (AI) accelerators), consumer electronics (e.g., smarter thermal management for compact devices like smartphones, tablets, and wearables), Internet of Things (IoT) and edge devices (e.g., scalable heat dissipation for small, high-density components), automotive and aerospace devices (e.g., reliable and adaptive cooling for extreme operational environments), and/or the like.

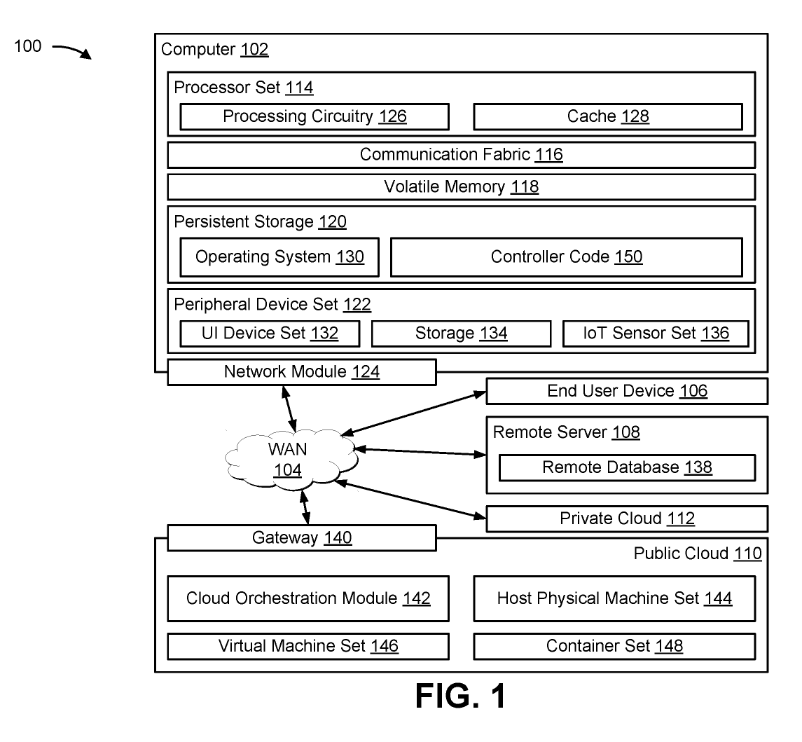

FIG. 1 is a diagram of an example computing environment 100 with devices capable of utilizing an adaptive thermal management system on, as described herein.

Computing environment 100 contains an example of an environment for the execution of at least some of the computer code involved in performing the inventive methods, such as controller code 150 (e.g., code for controller a thermal management system). In addition to controller code 150, computing environment 100 includes, for example, a computer 102, a wide area network (WAN) 104, an end user device (EUD) 106, a remote server 108, a public cloud 110, and a private cloud 112. In this embodiment, computer 102 includes a processor set 114 (including processing circuitry 126 and a cache 128), a communication fabric 116, a volatile memory 118, persistent storage 120 (including an operating system 130 and controller code 150, as identified above), a peripheral device set 122 (including a user interface (UI) device set 132, storage 134, and an Internet of Things (IoT) sensor set 136), and a network module 124. Remote server 108 includes a remote database 138. Public cloud 110 includes a gateway 140, a cloud orchestration module 142, a host physical machine set 144, a virtual machine set 146, and a container set 148.

Computer 102 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network, or querying a database, such as remote database 138. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 102, to keep the presentation as simple as possible. Computer 102 may be located in a cloud, even though it is not shown in a cloud in FIG. 1. On the other hand, computer 102 is not required to be in a cloud except to any extent as may be affirmatively indicated.

Processor set 114 includes one, or more, computer processors of any type now known or to be developed in the future. Processing circuitry 126 may be distributed over multiple packages (for example, multiple, coordinated integrated circuit chips). Processing circuitry 126 may implement multiple processor threads and/or multiple processor cores. Cache 128 is memory that is located in the processor chip package(s) and is typically used for data or code that should be available for rapid access by the threads or cores running on processor set 114. Cache memories are typically organized into multiple levels depending upon relative proximity to the processing circuitry. Alternatively, some, or all, of the cache for the processor set may be located “off chip.” In some computing environments, processor set 114 may be designed for working with qubits and performing quantum computing.

Computer-readable program instructions are typically loaded onto computer 102 to cause a series of operational steps to be performed by processor set 114 of computer 102 and thereby effect a computer-implemented method, such that the instructions thus executed will instantiate the methods specified in flowcharts and/or narrative descriptions of computer-implemented methods included in this document (collectively referred to as “the inventive methods”). These computer-readable program instructions are stored in various types of computer-readable storage media, such as cache 128 and the other storage media discussed below. The program instructions, and associated data, are accessed by processor set 114 to control and direct performance of the inventive methods. In computing environment 100, at least some of the instructions for performing the inventive methods may be stored in controller code 150 in persistent storage 120.

Communication fabric 116 is the signal conduction path that allows the various components of computer 102 to communicate with each other. Typically, this fabric is made of switches and electrically conductive paths, such as the switches and electrically conductive paths that make up buses, bridges, physical input/output ports and the like. Other types of signal communication paths may be used, such as fiber optic communication paths and/or wireless communication paths.

Volatile memory 118 is any type of volatile memory now known or to be developed in the future. Examples include dynamic type random access memory (RAM) or static type RAM. Typically, volatile memory 118 is characterized by random access, but this is not required unless affirmatively indicated. In computer 102, the volatile memory 118 is located in a single package and is internal to computer 102, but, alternatively or additionally, the volatile memory may be distributed over multiple packages and/or located externally with respect to computer 102.

Persistent storage 120 is any form of non-volatile storage for computers that is now known or to be developed in the future. The non-volatility of this storage means that the stored data is maintained regardless of whether power is being supplied to computer 102 and/or directly to persistent storage 120. Persistent storage 120 may be a read only memory (ROM), but typically at least a portion of the persistent storage allows writing of data, deletion of data, and re-writing of data. Some familiar forms of persistent storage include magnetic disks and solid-state storage devices. Operating system 130 may take any of several forms, such as various known proprietary operating systems or open source Portable Operating System Interface-type operating systems that employ a kernel.

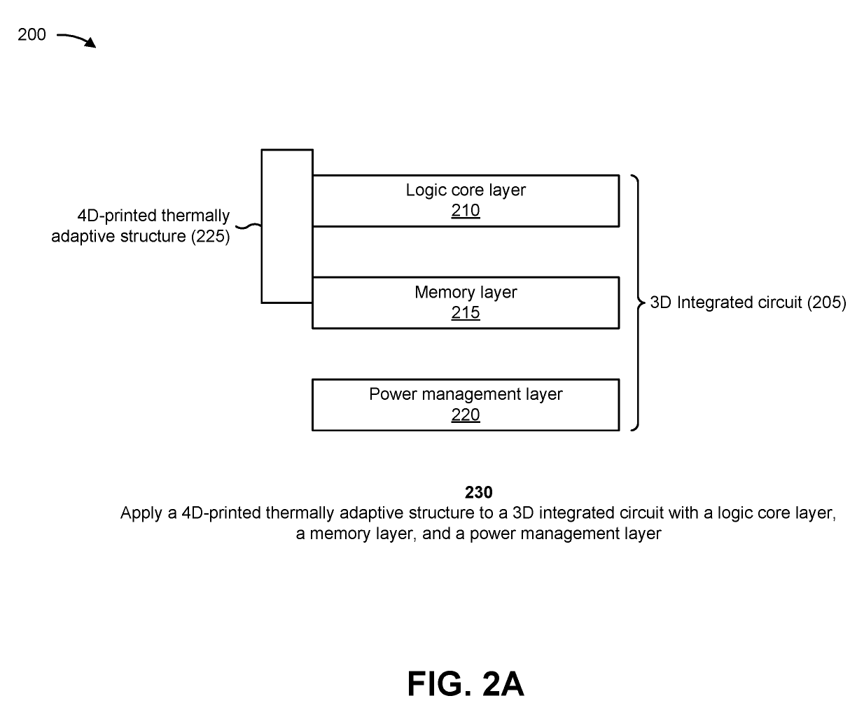

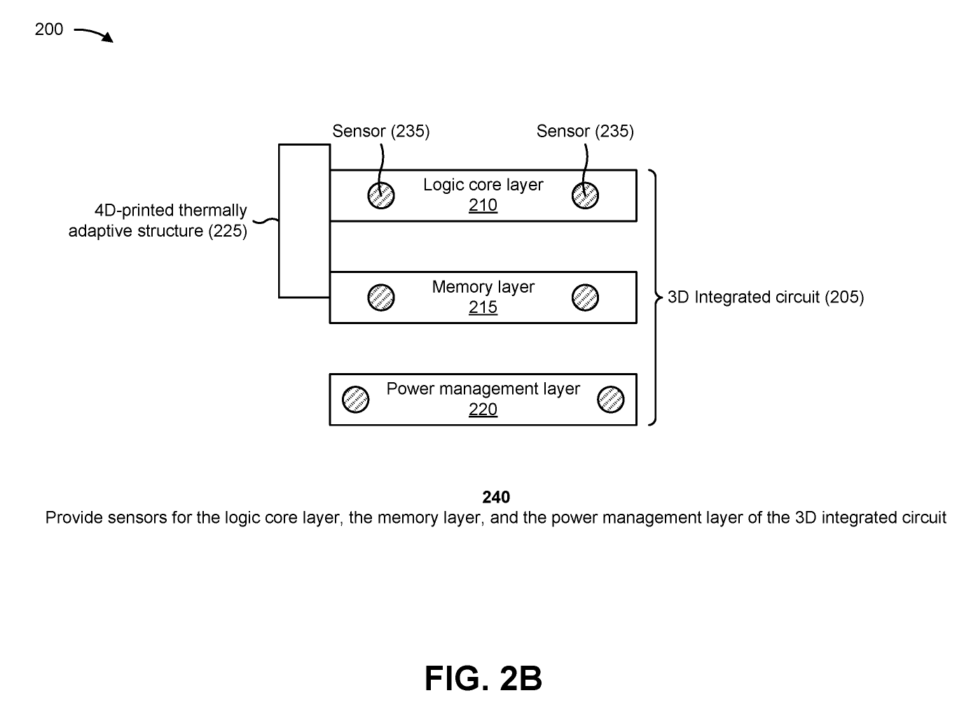

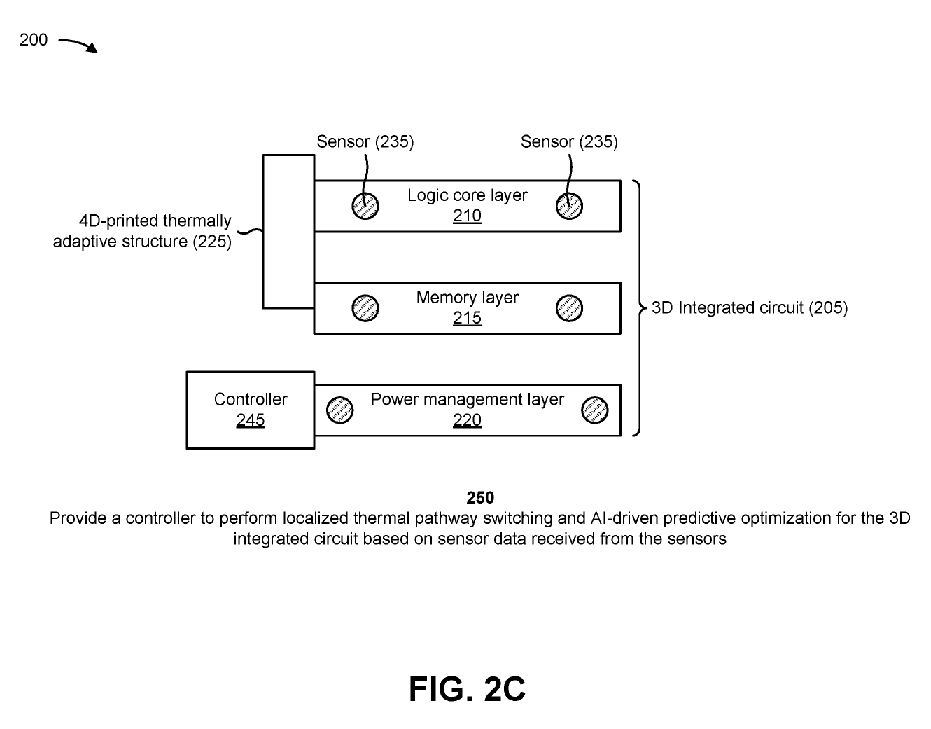

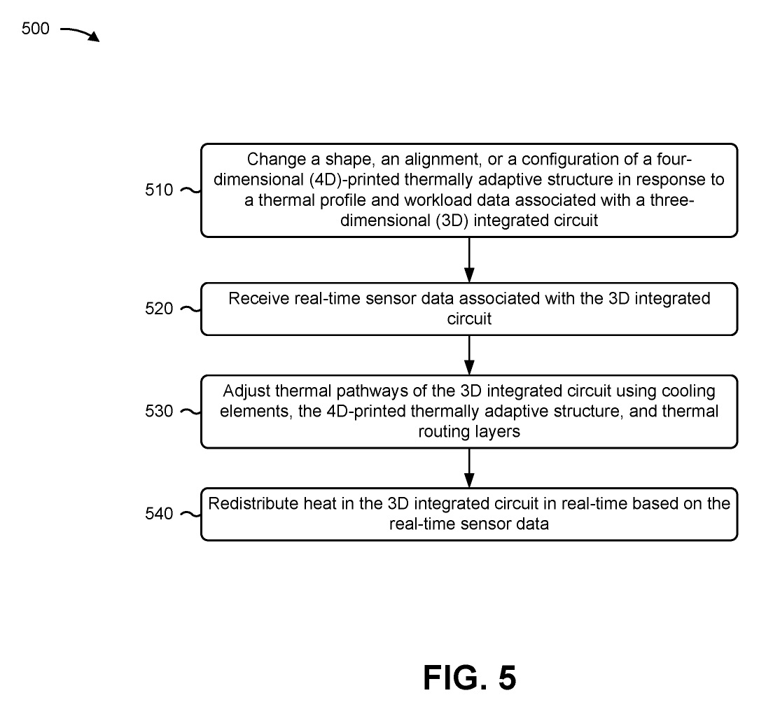

The code included in the controller code 150 typically includes at least some of the computer code involved in performing one or more operations described herein, such as the operations of the implementations described in FIGS. 2A-2C, 3A-4G, and 4A-4D and the process described in FIG. 5.

Peripheral device set 122 includes the set of peripheral devices of computer 102. Data communication connections between the peripheral devices and the other components of computer 102 may be implemented in various ways, such as Bluetooth® connections, Near-Field Communication (NFC) connections, connections made by cables (such as universal serial bus (USB) type cables), insertion-type connections (for example, secure digital (SD) card), connections made through local area communication networks and/or connections made through wide area networks such as the internet. In various embodiments, UI device set 132 may include components such as a display screen, speaker, microphone, wearable devices (such as goggles and smart watches), keyboard, mouse, printer, touchpad, game controllers, and/or haptic devices. Storage 134 is external storage, such as an external hard drive, or insertable storage, such as an SD card. Storage 134 may be persistent and/or volatile. In some embodiments, storage 134 may take the form of a quantum computing storage device for storing data in the form of qubits. In embodiments where computer 102 is required to have a large amount of storage (for example, where computer 102 locally stores and manages a large database), this storage may be provided by peripheral storage devices designed for storing very large amounts of data, such as a storage area network (SAN) that is shared by multiple, geographically distributed computers. IoT sensor set 136 is made up of sensors that can be used in Internet of Things applications. For example, one sensor may be a thermometer and another sensor may be a motion detector.

Network module 124 is the collection of computer software, hardware, and firmware that allows computer 102 to communicate with other computers through WAN 104. Network module 124 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 124 are performed on the same physical hardware device. In other embodiments (for example, embodiments that utilize software-defined networking (SDN)), the control functions and the forwarding functions of network module 124 are performed on physically separate devices, such that the control functions manage several different network hardware devices. Computer-readable program instructions for performing the inventive methods can typically be downloaded to computer 102 from an external computer or external storage device through a network adapter card or network interface included in network module 124.

WAN 104 is any wide area network (for example, the internet) capable of communicating computer data over non-local distances by any technology for communicating computer data, now known or to be developed in the future. In some embodiments, the WAN 104 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and/or edge servers.

EUD 106 is any computer system that is used and controlled by an end user (for example, a customer of an enterprise that operates computer 102), and may take any of the forms discussed above in connection with computer 102. EUD 106 typically receives helpful and useful data from the operations of computer 102. For example, in a hypothetical case where computer 102 is designed to provide a recommendation to an end user, this recommendation would typically be communicated from network module 124 of computer 102 through WAN 104 to EUD 106. In this way, EUD 106 can display, or otherwise present, the recommendation to an end user. In some embodiments, EUD 106 may be a client device, such as thin client, heavy client, mainframe computer, desktop computer and so on.

Remote server 108 is any computer system that serves at least some data and/or functionality to computer 102. Remote server 108 may be controlled and used by the same entity that operates computer 102. Remote server 108 represents the machine(s) that collect and store helpful and useful data for use by other computers, such as computer 102. For example, in a hypothetical case where computer 102 is designed and programmed to provide a recommendation based on historical data, this historical data may be provided to computer 102 from remote database 138 of remote server 108.

Public cloud 110 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 110 is performed by the computer hardware and/or software of cloud orchestration module 142. The computing resources provided by public cloud 110 are typically implemented by virtual computing environments that run on various computers making up the computers of host physical machine set 144, which is the universe of physical computers in and/or available to public cloud 110. The virtual computing environments (VCEs) typically take the form of virtual machines from virtual machine set 146 and/or containers from container set 148. These VCEs may be stored as images and may be transferred among and between the various physical machine hosts, either as images or after instantiation of the VCE. Cloud orchestration module 142 manages the transfer and storage of images, deploys new instantiations of VCEs, and manages active instantiations of VCE deployments. Gateway 140 is the collection of computer software, hardware, and firmware that allows public cloud 110 to communicate through WAN 104.

Some further explanation of VCEs will now be provided. VCEs can be stored as “images.” A new active instance of a VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

Private cloud 112 is similar to public cloud 110, except that the computing resources are only available for use by a single enterprise. While private cloud 112 is depicted as being in communication with WAN 104, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this example, public cloud 110 and private cloud 112 are both part of a larger hybrid cloud.

Cloud computing services and/or microservices (not separately shown in FIG. 1): private and public clouds 110 are programmed and configured to deliver cloud computing services and/or microservices (unless otherwise indicated, the word “microservices” shall be interpreted as inclusive of larger “services” regardless of size). Cloud services are infrastructure, platforms, or software that are typically hosted by third-party providers and made available to users through the internet. Cloud services facilitate the flow of user data from front-end clients (for example, user-side servers, tablets, desktops, laptops), through the internet, to the provider’s systems, and back. In some embodiments, cloud services may be configured and orchestrated according to an “as a service” technology paradigm where content is being presented to an internal or external customer in the form of a cloud computing service. As-a-service offerings typically provide endpoints with which various customers interface. These endpoints are typically based on a set of application programming interfaces (APIs). One category of as-a-service offering is Platform as a Service (PaaS), where a service provider provisions, instantiates, runs, and manages a modular bundle of code that customers can use to instantiate a computing platform and one or more applications, without the complexity of building and maintaining the infrastructure typically associated with such tasks. Another category is Software-as-a-Service (SaaS) where software is centrally hosted and allocated on a subscription basis. SaaS is also known as on-demand software, web-based software, or web-hosted software. Four technological sub-fields involved in cloud services are: deployment, integration, on demand, and virtual private networks.

The number and arrangement of devices and networks shown in FIG. 1 are provided as an example. In practice, there may be additional devices and/or networks, fewer devices and/or networks, different devices and/or networks, or differently arranged devices and/or networks than those shown in FIG. 1. Furthermore, two or more devices shown in FIG. 1 may be implemented within a single device, or a single device shown in FIG. 1 may be implemented as multiple, distributed devices. Additionally, or alternatively, a set of devices (e.g., one or more devices) of the computing environment 100 may perform one or more functions described as being performed by another set of devices of the computing environment 100.

FIGS. 2A-2C are diagrams of an example 200 associated with providing an adaptive thermal management system for 3D integrated circuits. As shown in FIGS. 2A-2C, the example 200 includes a 3D integrated circuit 205 with a logic core layer 210, a memory layer 215, and a power management layer 220. The 3D integrated circuit may be provided in one or more devices or components described above in connection with FIG. 1. For example, the 3D integrated circuit 205 may be provided in the computer 102, the end user device 106, the remote server 108, a system provided by the public cloud 110, and/or a system provided by the private cloud 112. Further details of the 3D integrated circuit 205, the logic core layer 210, the memory layer 215, and the power management layer 220 are provided elsewhere herein.

The 3D integrated circuit 205 may include a type of integrated circuit that stacks multiple layers of transistors, interconnects, and other components in a vertical configuration. The 3D integrated circuit 205 may be designed to increase the density of transistors and other components on a single chip, while also improving performance and reducing power consumption. The multiple layers of the 3D integrated circuit 205 may be stacked on top of each other, with each layer being connected to other layers through a network of interconnects, such as through-silicon vias or wire bonds. The 3D integrated circuit 205 may include the logic core layer 210 that contains processing logic, such as transistors, gates, and registers that perform computational functions of the 3D integrated circuit 205. The 3D integrated circuit 205 may include the memory layer 215 that contains memory cells that store data used by the processing logic. The 3D integrated circuit 205 may include the power management layer 220 that contains power management components, such as voltage regulators and power switches, that control the flow of power to the different layers of the 3D integrated circuit 205. In some implementations, the 3D integrated circuit 205 may include an input/output (I/O) layer that contains interfaces and buffers that connect the 3D integrated circuit 205 to external devices, such as other chips or peripheral components. In some implementations, the 3D integrated circuit 205 may include a thermal management layer that contains components, such as heat sinks and thermal sensors, that help manage the temperature of the 3D integrated circuit 205.

The multiple layers of the 3D integrated circuit 205 may be fabricated using a combination of different materials and processes, such as silicon (e.g., a primary material used for the fabrication of the logic core, memory, and power management layers), interconnect materials (e.g., materials, such as copper or aluminum, that are used to connect the different layers of the 3D integrated circuit 205), through-silicon vias (e.g., vertical interconnects that connect the different layers of the 3D integrated circuit 205 through the silicon substrate), and wire bonds (e.g., that connect the 3D integrated circuit 205 to external devices or peripheral components). The 3D integrated circuit 205 requires careful thermal management to ensure optimal performance and reliability.

As shown in FIG. 2A, and by reference number 230, a 4D-printed thermally adaptive structure 225 may be applied to the 3D integrated circuit 205 with the logic core layer 210, the memory layer 215, and the power management layer 220. For example, the 4D-printed thermally adaptive structure 225 may be connected to the 3D integrated circuit 205 (e.g., connected to one or more of the logic core layer 210, the memory layer 215, and the power management layer 220. The 4D-printed thermally adaptive structure 225 may include a 3D structure object that has been fabricated using advanced manufacturing techniques, such as 3D printing, and has the ability to change its shape, properties, or functionality over time in response to various stimuli, such as temperature, light, or moisture. The term “4D” refers to four dimensions: three dimensions of space, such as length, width, and depth, and one dimension of time. In some implementations, the 4D-printed thermally adaptive structure 225 may be fabricated from shape-memory polymers (e.g., that change shape in response to a temperature or light stimulus and revert to an original shape when the stimulus is removed), self-healing materials (e.g., that can repair themselves in response to damage or degradation), self-assembly systems (e.g., that can assemble or disassemble themselves in response to specific stimuli), dynamic structures (e.g., that can change shape or properties in response to external stimuli, such as vibration or wind), and/or the like.

Once the 4D-printed thermally adaptive structure 225 is fabricated, the 4D-printed thermally adaptive structure 225 may be applied to one or more layers of the 3D integrated circuit 205 using a suitable bonding process. The bonding process may involve the use of adhesives, such as epoxies or polyurethanes, or other bonding agents that provide a strong and reliable bond between the 4D-printed thermally adaptive structure 225 and the one or more layers of the 3D integrated circuit 205.

In some implementations, the 4D-printed thermally adaptive structure 225 may be designed to change shape, alignment, or configuration in response to environmental triggers, such as heat or electrical stimuli. The adaptability of the 4D-printed thermally adaptive structure 225 may enable thermal pathways to evolve in real-time, adjusting to dynamic workloads and thermal profiles of the 3D integrated circuit 205. Alternatively, or additionally, the 4D-printed thermally adaptive structure 225 may focus heat dissipation efforts on regions of the 3D integrated circuit 205 experiencing thermal stress (e.g., the logic core layer or the memory layer). By altering its structure, the 4D-printed thermally adaptive structure 225 may ensure that heat is effectively redirected without compromising other functions. Alternatively, or additionally, the 4D-printed thermally adaptive structure 225 may repair or reconfigure itself if damaged by prolonged stress, wear, or operational failures. This feature may ensure long-term reliability and may reduce maintenance needs. Alternatively, or additionally, the 4D-printed thermally adaptive structure 225 may enhance the effects of software-defined thermal pathways by physically adapting in order to improve heat flow in the direction prioritized by a controller 245 of the thermal management system, described below. For example, micro-channels within the 4D-printed thermally adaptive structure 225 may expand or contract to enhance heat transfer to a specific area. Alternatively, or additionally, as the 3D integrated circuit 205 ages or performance requirements of the 3D integrated circuit 205 change, the 4D-printed thermally adaptive structure 225 may reconfigure over time, maintaining optimal thermal performance across a lifecycle of the 3D integrated circuit 205. This may be particularly valuable in applications where longevity and reliability are important (e.g., in data centers or aerospace applications).

In some implementations, the 4D-printed thermally adaptive structure 225 may include several different types of structures. For example, the 4D-printed thermally adaptive structure 225 may include a thermally responsive micro-channel. A thermally responsive micro-channel may include a microfluidic channel fabricated using 4D-printed materials and that can expand or contract based on real-time heat data, directing coolant, or enhancing heat dissipation. In another example, the 4D-printed thermally adaptive structure 225 may include a shape-memory heat fin. A shape-memory heat fin may include a 4D-printed fin that can change orientation or density to maximize airflow or contact with a surrounding environment, and to dynamically optimize heat transfer. In still another example, the 4D-printed thermally adaptive structure 225 may include a thermal insulating and conductive layer. A thermal insulating and conductive layer can reconfigure to switch between insulating and conducting properties, enabling precise control over heat flow to different regions of the 3D integrated circuit 205. In this way, the 4D-printed thermally adaptive structure 225 may provide adaptability (e.g., by enabling the thermal management system to respond in real-time to changing thermal profiles), scalability (e.g., may be customized for different integrated circuit designs and performance requirements), durability (e.g., self-healing properties extend the operational lifespan of the thermal management system), and energy efficiency (e.g., reduces a need for active cooling systems by optimizing heat flow naturally).

As shown in FIG. 2B, and by reference number 240, sensors 235 may be provided for the logic core layer 210, the memory layer 215, and the power management layer 220 of the 3D integrated circuit 205. For example, the sensors 235 may be distributed across the 3D integrated circuit 205 to provide real-time sensor data (e.g., temperature data and workload data). In some implementations, the sensors 235 may be distributed across the logic core layer 210, the memory layer 215, and the power management layer 220 of the 3D integrated circuit 205. One or more of the sensors 235 used in the 3D integrated circuit 205 may include a temperature or thermal sensor that measures the temperature of the 3D integrated circuit 205 and can be used to monitor thermal hotspots, detect overheating, and optimize thermal management. Alternatively, or additionally, one or more of the sensors 235 may include a voltage sensor that measures voltage levels in the 3D integrated circuit 205 and can be used to monitor power consumption, detect voltage drops, and optimize power management. Alternatively, or additionally, one or more of the sensors 235 may include a current sensor that measures current flowing through the 3D integrated circuit 205 and can be used to monitor power consumption, detect current spikes, and optimize power management. Alternatively, or additionally, one or more of the sensors 235 may include a humidity sensor that measures the humidity levels in the 3D integrated circuit 205 and can be used to monitor moisture levels, detect water ingress, and optimize reliability. Alternatively, or additionally, one or more of the sensors 235 may include a mechanical stress sensor that measures the mechanical stress in the 3D integrated circuit 205 and can be used to monitor warpage, detect cracks, and optimize reliability

Proper placement of the sensors 235 in the 3D integrated circuit 205 may ensure accurate measurements and optimal performance. The sensors 235 can be placed in various locations of the 3D integrated circuit 205, including the logic core layer 210. For example, thermal sensors may be placed near hotspots in the logic core layer 210 to monitor thermal gradients and optimize thermal management. Alternatively, or additionally, the sensors 235 may be placed in the memory layer 215. For example, voltage sensors may be placed near memory cells in the memory layer 215 to monitor voltage levels and optimize power management. Alternatively, or additionally, the sensors 235 may be placed in the power management layer 220. For example, current sensors may be placed near power rails in the power management layer 220 to monitor power consumption and optimize power management. Alternatively, or additionally, the sensors 235 may be placed in interface layers. For example, humidity sensors may be placed near interface layers to monitor moisture levels and optimize reliability. Alternatively, or additionally, the sensors 235 may be placed on a package substrate. For example, mechanical stress sensors may be placed on the package substrate to monitor warpage and optimize reliability.

In some implementations, the sensors 235 may be monolithically integrated into the 3D integrated circuit 205 using the same fabrication process as the logic core layer 210, memory layer 215, and power management layer 220. Alternatively, the sensors 235 may be hybrid integrated into the 3D integrated circuit 205 using a separate fabrication process and then bonded to the 3D integrated circuit 205. Alternatively, the sensors 235 may be discrete components that are mounted on the 3D integrated circuit 205 or on a separate substrate. In some implementations, the sensors 235 may connect and communicate with the controller 245 of the thermal management system, described below. In some implementations, the sensors 235 may be calibrated to ensure accurate measurements and optimal performance.

As shown in FIG. 2C, and by reference number 250, a controller 245 may be provided to perform localized thermal pathway switching and AI-driven predictive optimization for the 3D integrated circuit 205 based on sensor data received from the sensors 235. For example, the controller 245 may be provided for the thermal management system and may perform various functions. The controller 245 may be implemented using a variety of architectures. For example, a microcontroller-based architecture may be utilized to implement the controller 245. Alternatively, a field-programmable gate array (FPGA)-based architecture may be utilized to implement the controller 245. Alternatively, an application-specific integrated circuit (ASIC)-based architecture may be utilized to implement the controller 245. The microcontroller, the FPGA, or the ASIC may be programmed to receive sensor data from the sensors 235, perform thermal pathway switching, and execute AI-driven predictive optimization models.

In some implementations, the controller 245 may provide a software-defined mechanism that identifies specific regions of the 3D integrated circuit 205 (e.g., the logic core layer 210, the memory layer 215, or the power management layer 220) and customizes thermal pathways for each identified region. The controller 245 may dynamically reconfigure the thermal pathways in real-time to prioritize critical functions of the 3D integrated circuit 205 while maintaining overall thermal balance. In some implementations, the controller 245 may include a machine learning model that processes the sensor data from the sensors, and predicts thermal and workload profiles of the 3D integrated circuit 205. The controller 245 may preemptively adjust the 4D-printed thermally adaptive structure 225 and/or the thermal pathways based on predicted thermal and workload profiles. This may ensure proactive thermal management of the 3D integrated circuit 205, and may minimize the risk of localized overheating in the 3D integrated circuit 205.

In this way, an adaptive thermal management system is provided for 3D integrated circuits. For example, the thermal management system may optimize thermal management in the 3D integrated circuit 205 by reducing the thermal resistance of the 3D integrated circuit 205. The thermal management system may maximize power consumption efficiency and may conserve energy sources. By efficiently dissipating heat in real-time, the thermal management system may reduce thermal stress and heat-induced noise, thus extending the lifespan and reliability of the 3D integrated circuit 205. Thus, the adaptive thermal management system conserves computing resources, networking resources, and/or the like that would otherwise have been consumed by failing to adapt to the dynamic and localized nature of heat generation in the 3D integrated circuit 205, relying on expensive and energy-intensive external cooling systems for the 3D integrated circuit 205, failing to adapt to changing thermal requirements of the 3D integrated circuit 205, and/or the like.

As indicated above, FIGS. 2A-2C are provided as an example. Other examples may differ from what is described with regard to FIGS. 2A-2C. The number and arrangement of components shown in FIGS. 2A-2C are provided as an example. In practice, there may be additional components, fewer component, different components, or differently arranged components than those shown in FIGS. 2A-2C. Furthermore, two or more components shown in FIGS. 2A-2C may be implemented within a single component, or a single component shown in FIGS. 2A-2C may be implemented as multiple, distributed components. Additionally, or alternatively, a set of components (e.g., one or more components) shown in FIGS. 2A-2C may perform one or more functions described as being performed by another set of components shown in FIGS. 2A-2C.

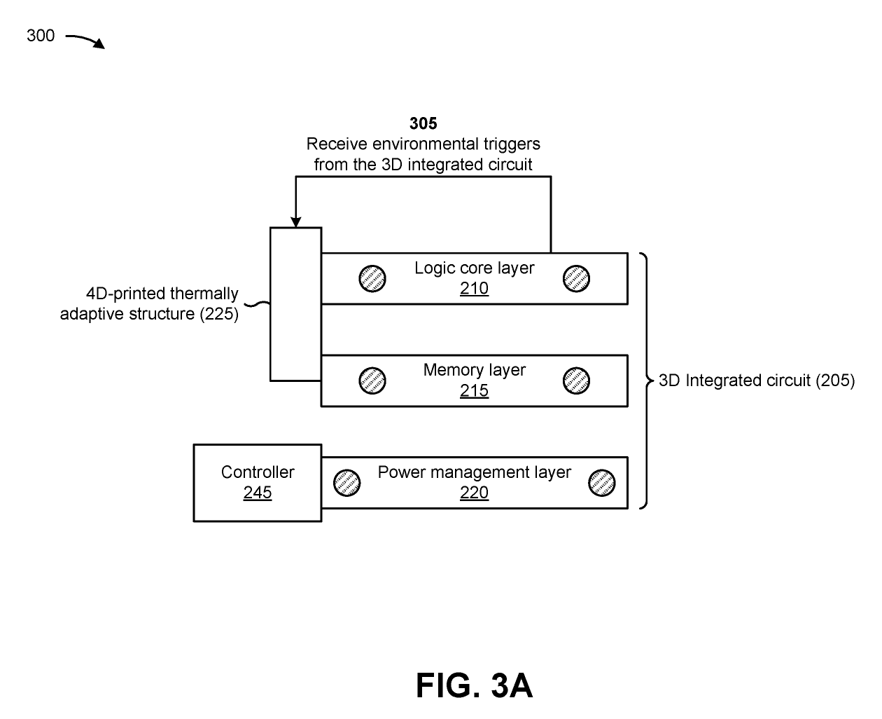

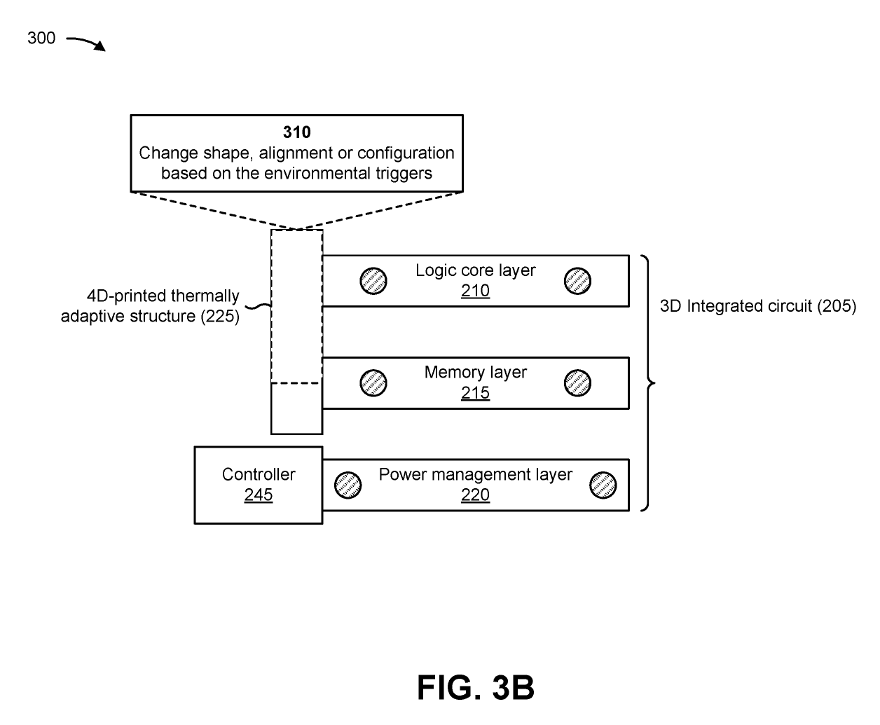

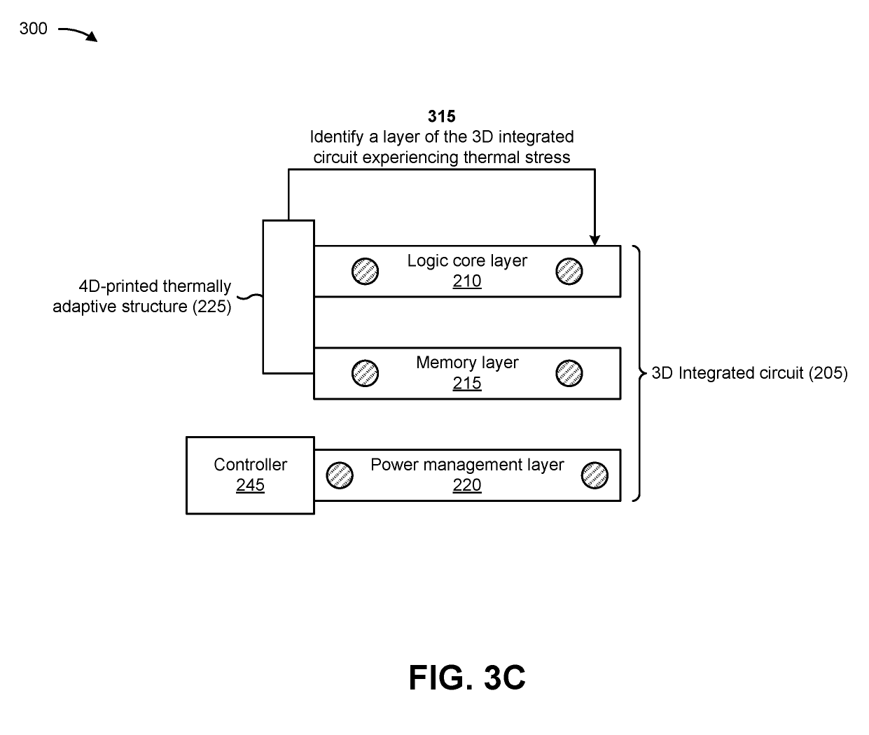

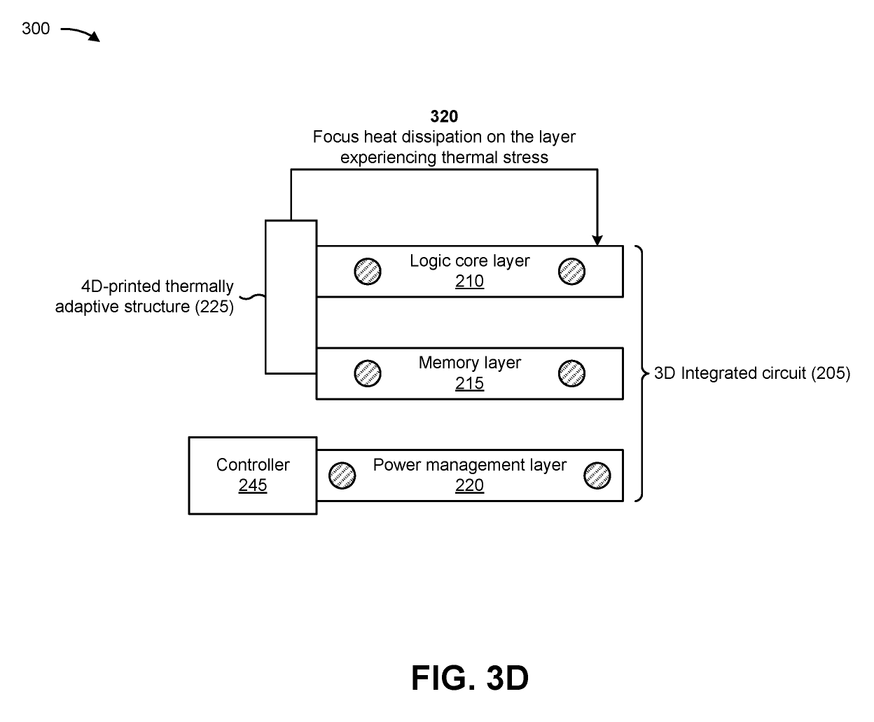

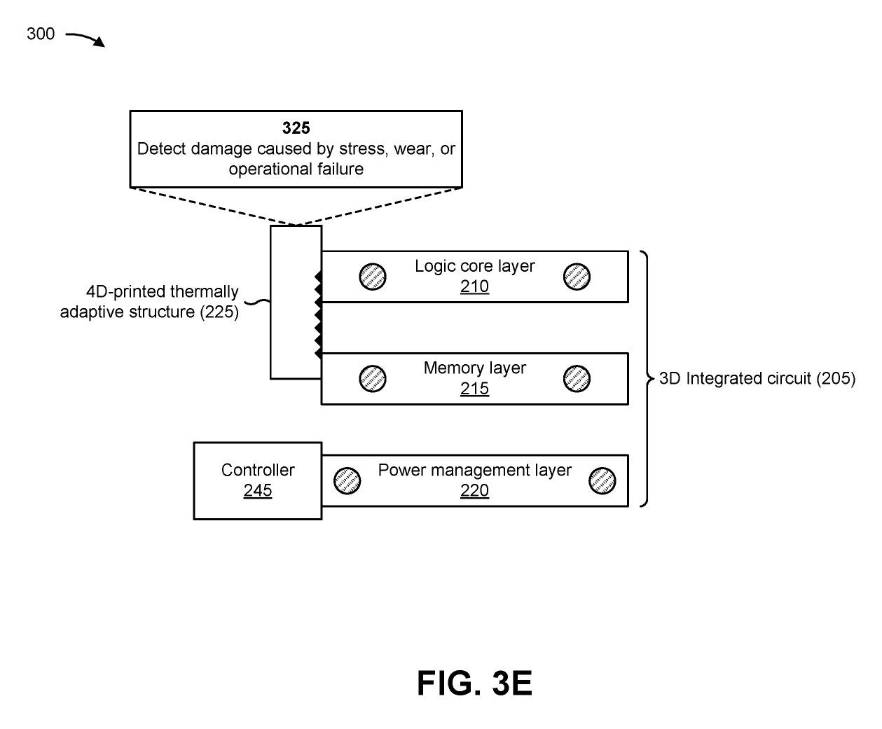

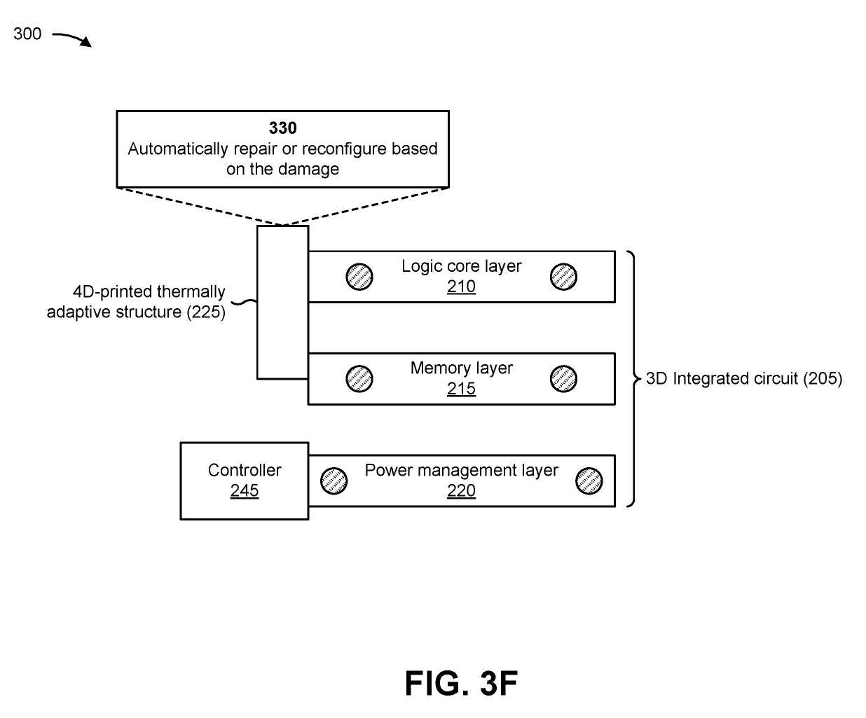

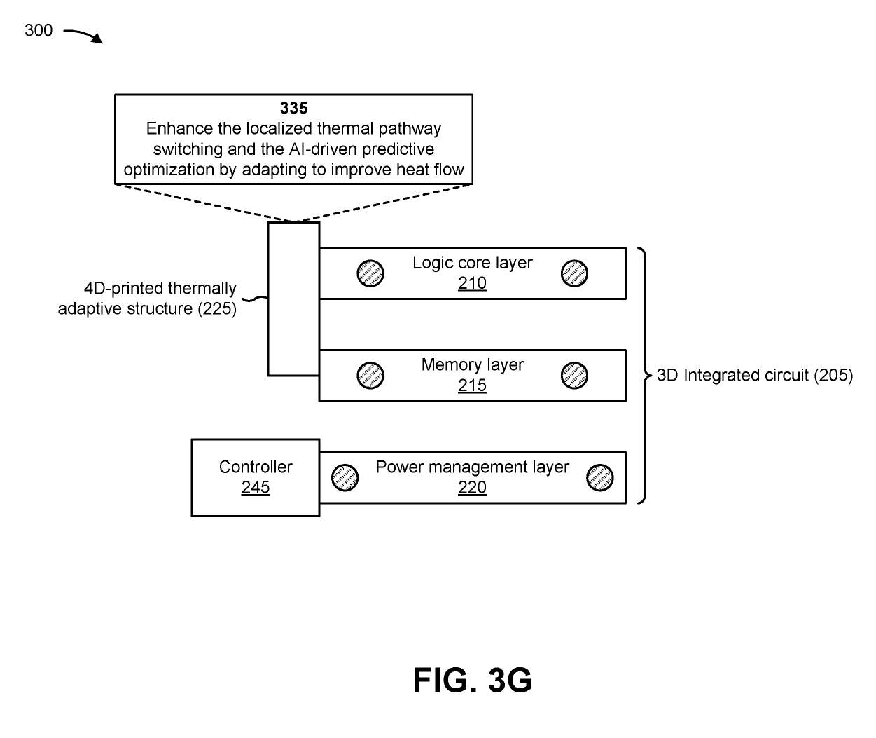

FIGS. 3A-3G are diagrams of example functions 300 capable of being performed by the 4D-printed thermally adaptive structure 225 of the thermal management system. As shown in FIG. 3A, and by reference number 305, the 4D-printed thermally adaptive structure 225 may receive environmental triggers from the 3D integrated circuit 205. For example, the 4D-printed thermally adaptive structure 225 may receive or be exposed to environmental triggers associated with the 3D integrated circuit 205. The 4D-printed thermally adaptive structure 225 may receive various environmental triggers from the 3D integrated circuit 205, such as temperature data, workload data, electrical signals, and/or the like.

As shown in FIG. 3B, and by reference number 310, the 4D-printed thermally adaptive structure 225 may change shape, alignment, or configuration based on the environmental triggers. For example, the 4D-printed thermally adaptive structure 225 may be designed to respond to the environmental triggers. In some implementations, the 4D-printed thermally adaptive structure 225 may change shape, alignment, or configuration in response to one or more of the environmental triggers. For example, the 4D-printed thermally adaptive structure 225 may be designed to respond to a workload experienced by the layers of the 3D integrated circuit 205 since the workload may generate excessive heat or vibrations. The 4D-printed thermally adaptive structure 225 may respond to temperature changes in the 3D integrated circuit 205. This can be achieved through the use of thermally sensitive materials, such as shape-memory alloys or polymers, that change shape or properties in response to temperature changes. The 4D-printed thermally adaptive structure 225 may expand or contract in response to temperature changes, allowing the structure to adjust a shape and properties to optimize thermal management. The 4D-printed thermally adaptive structure 225 may respond to humidity changes in the 3D integrated circuit 205. This can be achieved through the use of humidity-sensitive materials, such as hydrogels or polymers, that change shape or properties in response to humidity changes. The 4D-printed thermally adaptive structure 225 may respond to electrical changes in the 3D integrated circuit 205. This can be achieved through the use of electrically sensitive materials, such as electroactive polymers or electromagnetically sensitive materials, that change shape or properties in response to electrical changes.

As shown in FIG. 3C, and by reference number 315, the 4D-printed thermally adaptive structure 225 may identify a layer of the 3D integrated circuit 205 experiencing thermal stress. For example, the 4D-printed thermally adaptive structure 225 may sense temperature changes in the 3D integrated circuit 205 through the use of temperature-sensitive materials that can detect temperature changes in the 3D integrated circuit 205. The 4D-printed thermally adaptive structure 225 may undergo a phase transition in response to temperature changes, allowing the 4D-printed thermally adaptive structure 225 to detect and identify areas (e.g., a layer) of thermal stress in the 3D integrated circuit 205. In some implementations, the 4D-printed thermally adaptive structure 225 may be made from materials that enable the 4D-printed thermally adaptive structure 225 to focus heat dissipation efforts on regions of the 3D integrated circuit 205 experiencing thermal stress (e.g., the logic core layer 210 or the memory layer 215).

As shown in FIG. 3D, and by reference number 320, the 4D-printed thermally adaptive structure 225 may focus heat dissipation on the layer experiencing thermal stress. For example, after the layer of the 3D integrated circuit 205 experiencing the thermal stress is identified, a material structure of the 4D-printed thermally adaptive structure 225 may be altered to ensure that heat is effectively redirected away from the layer experiencing the thermal stress and without compromising other functions.

As shown in FIG. 3E, and by reference number 325, the 4D-printed thermally adaptive structure 225 may detect damage caused by stress, wear, or operational failure. For example, the 4D-printed thermally adaptive structure 225 may be damaged over time due to stress, wear, and/or operational failure of the material forming the 4D-printed thermally adaptive structure 225. In some implementations, the 4D-printed thermally adaptive structure 225 may detect the damage when the 4D-printed thermally adaptive structure 225 fails to function properly.

As shown in FIG. 3F, and by reference number 330, the 4D-printed thermally adaptive structure 225 may automatically repair or reconfigure itself based on the damage. For example, the 4D-printed thermally adaptive structure 225 may automatically repair or reconfigure itself if the damage is caused by prolonged stress, wear, or operational failures. This may ensure long-term reliability and reduce maintenance needs associated with the 4D-printed thermally adaptive structure 225. Furthermore, as the 3D integrated circuit 205 ages or experiences a performance requirement change, the 4D-printed thermally adaptive structure 225 may reconfigure over time, to maintain optimal thermal performance across a lifecycle of the 3D integrated circuit 205. This may be particularly valuable in applications where longevity and reliability are important (e.g., in data centers or aerospace applications).

As shown in FIG. 3G, and by reference number 335, the 4D-printed thermally adaptive structure 225 may enhance the localized thermal pathway switching and the AI-driven predictive optimization by adapting in order to improve heat flow. For example, the 4D-printed thermally adaptive structure 225 may amplify the effect of software-defined thermal pathways by physically adapting to improve heat flow in a direction prioritized by the controller 245. In one example, micro-channels within the 4D-printed thermally adaptive structure 225 may expand or contract to enhance heat transfer to a specific area. In some implementations, the 4D-printed thermally adaptive structure 225 may enhance the localized thermal pathway switching and the AI-driven predictive optimization by expanding or contracting in response to temperature changes, allowing the 4D-printed thermally adaptive structure 225 to improve heat flow and reduce thermal gradients. Alternatively, or additionally, the 4D-printed thermally adaptive structure 225 may enhance the localized thermal pathway switching and the AI-driven predictive optimization by utilizing shape memory alloys that can change shape in response to temperature changes, allowing the 4D-printed thermally adaptive structure 225 to improve heat flow and reduce thermal gradients. Alternatively, or additionally, the 4D-printed thermally adaptive structure 225 may enhance the localized thermal pathway switching and the AI-driven predictive optimization by utilizing thermo-responsive polymers that can change shape or properties in response to temperature changes, improve heat flow, and reduce thermal gradients.

As indicated above, FIGS. 3A-3G are provided as an example. Other examples may differ from what is described in connection with FIGS. 3A-3G.

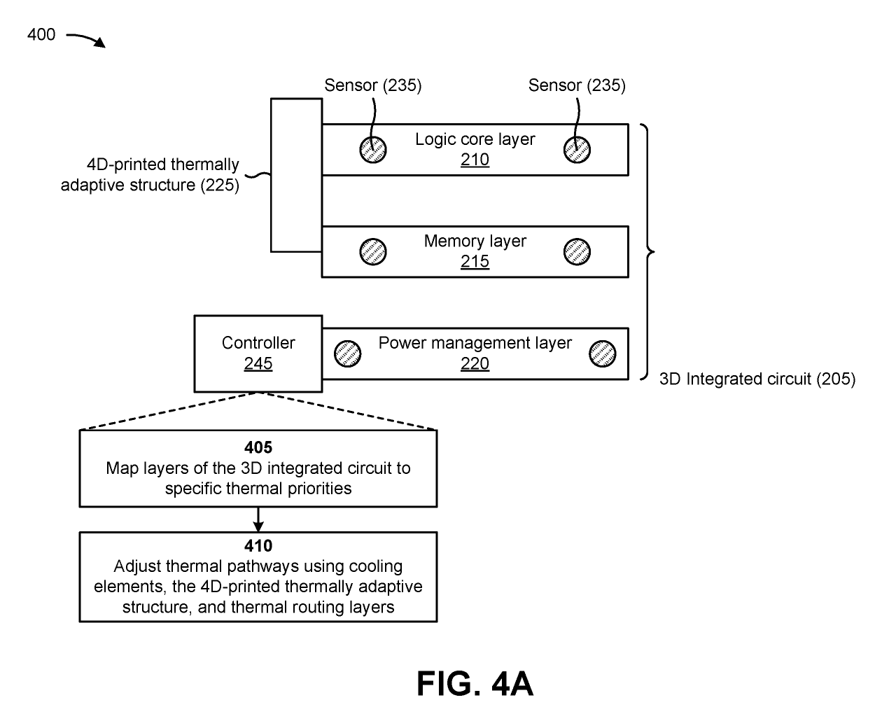

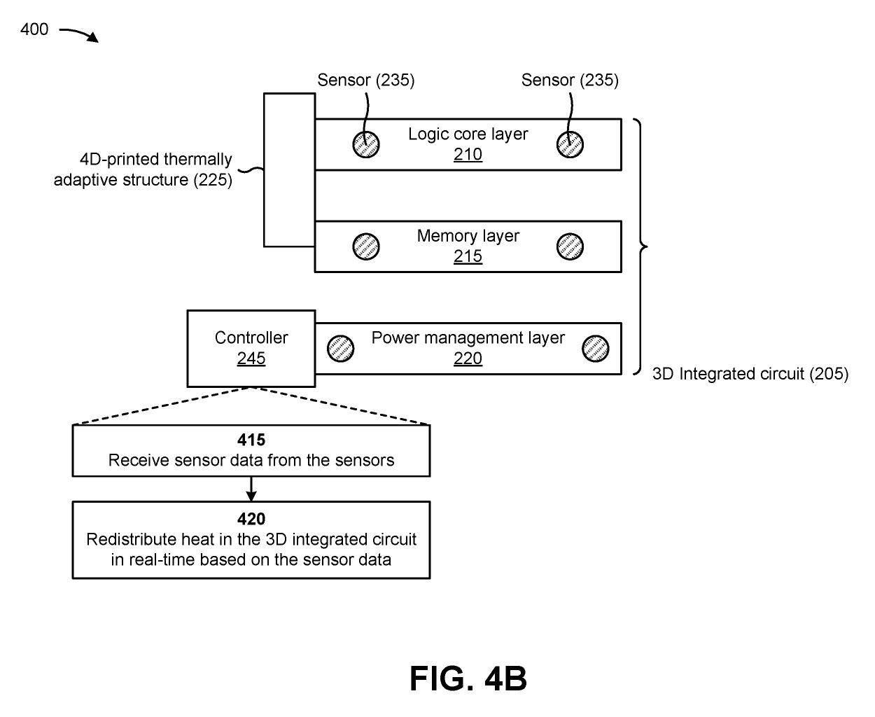

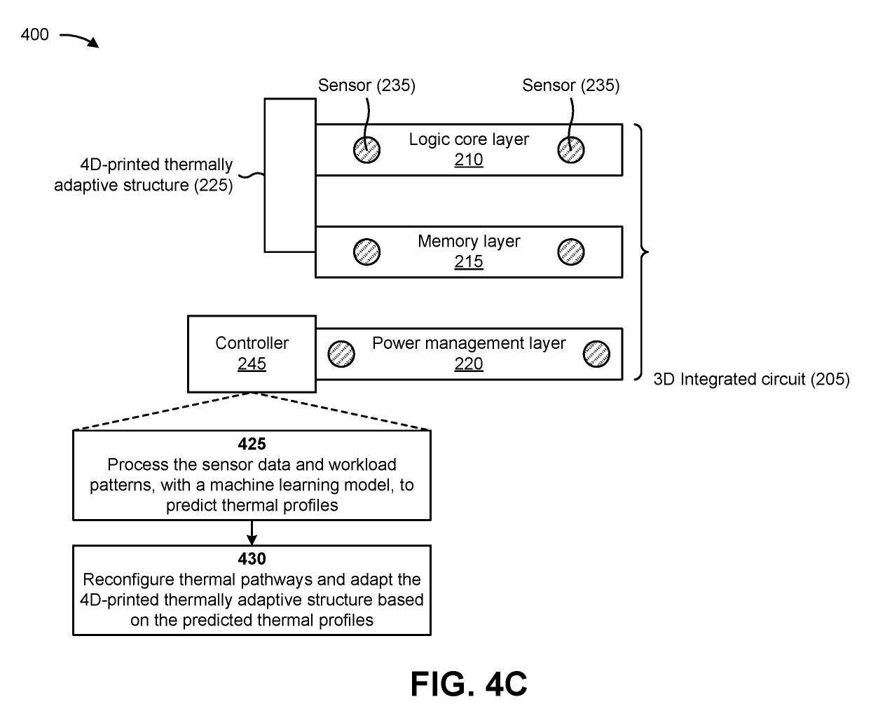

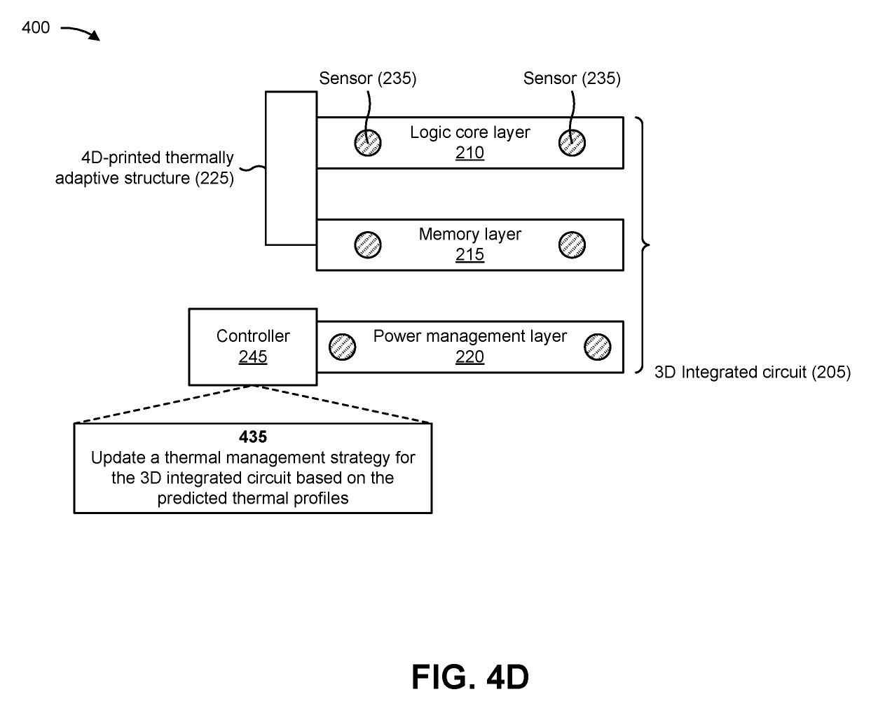

FIGS. 4A-4D are diagrams of example functions 400 capable of being performed by the controller 245 of the thermal management system. As shown in FIG. 4A, and by reference number 405, the controller 245 may map layers of the 3D integrated circuit 205 to specific thermal priorities. For example, the controller 245 may map the layers of the 3D integrated circuit 205 to specific thermal priorities by thermal profiling. The controller 245 may create a thermal profile of the 3D integrated circuit 205, and may utilize the thermal profile to identify areas of high thermal stress and prioritize thermal management. Alternatively, the controller 245 may create a temperature map of the 3D integrated circuit 205, and may utilize the temperature map to identify areas of high temperature and prioritize thermal management. In some implementations, the controller 245 may create a thermal profile for each layer of the 3D integrated circuit 205, and may utilize the thermal profiles to prioritize thermal management based on the thermal stress of each layer.

As further shown in FIG. 4A, and by reference number 410, the controller 245 may adjust thermal pathways using cooling elements, the 4D-printed thermally adaptive structure 225, and thermal routing layers. For example, the controller 245 may control operation of cooling elements, such as fans or heat sinks, to adjust thermal pathways and optimize thermal management. The controller 245 may control the 4D-printed thermally adaptive structure 225 to adjust thermal pathways and optimize thermal management. For example, the controller 245 may control the shape memory of the 4D-printed thermally adaptive structure 225 to adjust thermal pathways and optimize thermal management. The controller 245 can control the thermal routing layers to adjust thermal pathways and optimize thermal management. For example, the controller 245 may control the thermal interface materials used in the thermal routing layers to optimize thermal conductivity and adjust thermal pathways, may switch between different thermal pathways in the thermal routing layers to optimize thermal management, and/or the like.

As shown in FIG. 4B, and by reference number 415, the controller 245 may receive sensor data from the sensors 235. For example, the sensors 235 may generate the sensor data (e.g., temperature data, workload data, and/or the like) in real-time, and may provide the sensor data to the controller 245 in real-time. In some implementations, the sensor data may include temperature sensor data (e.g., data from sensors that measure temperature changes in the 3D integrated circuit 205), humidity sensor data (e.g., data from sensors that measure humidity changes in the 3D integrated circuit 205), pressure sensor data (e.g., data from sensors that measure pressure changes in the 3D integrated circuit 205), energy consumption data (e.g., data from sensors that measure energy consumption in the 3D integrated circuit 205), noise quantification data (e.g., data from sensors that measure noise levels in the 3D integrated circuit 205), thermal conductivity data (e.g., data from sensors that measure thermal conductivity in the 3D integrated circuit 205), electrical resistance data (e.g., data from sensors that measure electrical resistance in the 3D integrated circuit 205), electrical impedance data (e.g., data from sensors that measure electrical impedance in the 3D integrated circuit 205), and/or the like.

As further shown in FIG. 4B, and by reference number 420, the controller 245 may redistribute heat in the 3D integrated circuit 205 in real-time based on the sensor data. For example, the controller 245 may cause heat in the 3D integrated circuit 205 to be redistributed in real-time based on the sensor data. This may ensure that high-priority functions of the 3D integrated circuit 205 remain operational while efficiently cooling less critical regions of the 3D integrated circuit 205. In some implementations, the controller 245 may cause switching between different thermal pathways in the 3D integrated circuit 205 to optimize heat redistribution, may cause dynamic thermal routing of heat through the 3D integrated circuit 205 to optimize heat redistribution, may cause optimization of thermal interface materials used in the 3D integrated circuit 205 to improve thermal conductivity and optimize heat redistribution, may control operation of cooling elements, such as fans or heat sinks, to optimize heat redistribution, and/or the like.

As shown in FIG. 4C, and by reference number 425, the controller 245 may process the sensor data and workload patterns, with a machine learning model, to predict thermal profiles. For example, the controller 245 may preprocess the sensor data and workload patterns to prepare the data for machine learning analysis. The preprocessing may include cleaning the sensor data and workload patterns to remove any errors or inconsistencies, normalizing the sensor data and workload patterns to ensure that they are in a suitable format for machine learning analysis, and transforming the sensor data and workload patterns to extract relevant features and improve the accuracy of the machine learning model. The machine learning model may include a neural network model, a decision tree model, a random forest model, and/or the like. The controller 245 may utilize supervised learning (e.g., with labeled data) or unsupervised learning (e.g., with unlabeled data) to train the machine learning model using the preprocessed sensor data and workload patterns. The controller 245 may utilize the trained machine learning model to predict thermal profiles based on real-time sensor data and workload patterns. The controller 245 may utilize the predicted thermal profiles to optimize thermal management and improve the overall performance and reliability of the 3D integrated circuit 205, to perform predictive maintenance on the 3D integrated circuit 205, such as scheduling maintenance or replacing components before they fail.

As further shown in FIG. 4C, and by reference number 430, the controller 245 may reconfigure thermal pathways and adapt the 4D-printed thermally adaptive structure 225 based on the predicted thermal profiles. For example, the controller 245 may redesign thermal pathways in the 3D integrated circuit 205 to optimize heat redistribution based on the predicted thermal profiles. The controller 245 may optimize the thermal interface materials used in the 3D integrated circuit 205 to improve thermal conductivity and optimize heat redistribution, may control the operation of cooling elements, such as fans or heat sinks, to optimize heat redistribution, and/or the like. Furthermore, the controller 245 may adapt the 4D-printed thermally adaptive structure 225 to optimize thermal management based on the predicted thermal profiles. For example, the controller 245 may control the shape of the 4D-printed thermally adaptive structure 225 to optimize thermal management.

As shown in FIG. 4D, and by reference number 435, the controller 245 may update a thermal management strategy for the 3D integrated circuit 205 based on the predicted thermal profiles. For example, the controller 245 may continuously refine the thermal management strategy for the 3D integrated circuit based on real-time and historical performance data. In some implementations, the controller 245 may update the thermal management strategy for the 3D integrated circuit 205 based on the predicted thermal profiles, through various mechanisms. For example, the controller 245 may optimize the thermal pathways in the 3D integrated circuit 205 to reduce thermal gradients and hotspots, may dynamically route heat through the 3D integrated circuit 205 to optimize thermal management, may optimize the thermal interface materials used in the 3D integrated circuit 205 to improve thermal conductivity and optimize thermal management, may control the operation of cooling elements, such as fans or heat sinks, to optimize thermal management, and/or the like.

As indicated above, FIGS. 4A-4D are provided as an example. Other examples may differ from what is described in connection with FIGS. 4A-4D.

FIG. 5 is a flowchart of an example process 500 associated with providing an adaptive thermal management system for 3D integrated circuits. One or more process blocks of FIG. 3 are performed by a thermal management system (e.g., computer 102, the 4D-printed thermally adaptive structure 225, and/or the controller 245) and/or by another component or a group of components separate from or including the thermal management system. Additionally, or alternatively, one or more process blocks of FIG. 5 may be performed by one or more components of computer 102, such as processor set 114, communication fabric 116, volatile memory 118, and/or controller code 150.

As shown in FIG. 5, process 500 may include changing a shape, an alignment, or a configuration of a 4D-printed thermally adaptive structure in response to a thermal profile and workload data associated with a 3D integrated circuit (block 510). For example, the thermal management system may change a shape, an alignment, or a configuration of a 4D-printed thermally adaptive structure in response to a thermal profile and workload data associated with a 3D integrated circuit, as described above. In some implementations, the 4D-printed thermally adaptive structure includes one of a microfluidic channel, a thermally conductive fin, or an expandable layer. In some implementations, the 4D-printed thermally adaptive structure evolves with usage patterns and aging associated with the 3D integrated circuit. In some implementations, the 4D-printed thermally adaptive structure is fabricated from a shape-memory polymer or a phase-change material that reacts to an environmental trigger.

As further shown in FIG. 5, process 500 may include receiving real-time sensor data associated with the 3D integrated circuit (block 520). For example, the thermal management system may receive real-time sensor data associated with the 3D integrated circuit, as described above. In some implementations, one or more sensors that generate the sensor data are distributed across a logic core layer, a memory layer, and a power management layer of the 3D integrated circuit.

As further shown in FIG. 5, process 500 may include adjusting thermal pathways of the 3D integrated circuit using cooling elements, the 4D-printed thermally adaptive structure, and thermal routing layers (block 530). For example, the thermal management system may adjust thermal pathways of the 3D integrated circuit using cooling elements, the 4D-printed thermally adaptive structure, and thermal routing layers, as described above.

As further shown in FIG. 5, process 500 may include redistributing heat in the 3D integrated circuit in real-time based on the real-time sensor data (block 540). For example, the thermal management system may redistribute heat in the 3D integrated circuit in real-time based on the real-time sensor data, as described above.

In some implementations, process 500 includes processing the real-time sensor data and the workload data, with a machine learning model, to generate predicted thermal profiles, and reconfiguring the thermal pathways and adapting the 4D-printed thermally adaptive structure based on the predicted thermal profiles. In some implementations, process 500 includes updating a thermal management strategy for the 3D integrated circuit based on the predicted thermal profiles. In some implementations, the machine learning model is trained on a dataset of thermal profiles and workload patterns.

In some implementations, process 500 includes enhancing the adjustment to the thermal pathways of the 3D integrated circuit by adapting the 4D-printed thermally adaptive structure to improve heat flow. In some implementations, process 500 includes directing thermal dissipation to one or more of a logic core layer, a memory layer, or a power management layer of the 3D integrated circuit. In some implementations, process 500 includes identifying a layer of the 3D integrated circuit experiencing thermal stress, and focusing heat dissipation on the layer experiencing thermal stress. In some implementations, process 500 includes detecting damage to the 4D-printed thermally adaptive structure, and repairing the damage.

Although FIG. 5 shows example blocks of process 500, in some implementations, process 500 may include additional blocks, fewer blocks, different blocks, or differently arranged blocks than those depicted in FIG. 5. Additionally, or alternatively, two or more of the blocks of process 500 may be performed in parallel.

The foregoing disclosure provides illustration and description, but is not intended to be exhaustive or to limit the implementations to the precise forms disclosed. Modifications may be made in light of the above disclosure or may be acquired from practice of the implementations. For example, various implementations of this disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

A computer program product embodiment (“CPP embodiment” or “CPP”) is a term used in this disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer-readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, RAM, ROM, erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits / lands formed in a major surface of a disc), or any suitable combination of the foregoing. A computer-readable storage medium, as that term is used in this disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

As used herein, the term “component” is intended to be broadly construed as hardware, firmware, or a combination of hardware and software. It will be apparent that systems and/or methods described herein may be implemented in different forms of hardware, firmware, and/or a combination of hardware and software. The actual specialized control hardware or software code used to implement these systems and/or methods is not limiting of the implementations. Thus, the operation and behavior of the systems and/or methods are described herein without reference to specific software code - it being understood that software and hardware can be used to implement the systems and/or methods based on the description herein.

As used herein, satisfying a threshold may, depending on the context, refer to a value being greater than the threshold, greater than or equal to the threshold, less than the threshold, less than or equal to the threshold, equal to the threshold, not equal to the threshold, or the like.

Although particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

When “a processor” or “one or more processors” (or another device or component, such as “a controller” or “one or more controllers”) is described or claimed (within a single claim or across multiple claims) as performing multiple operations or being configured to perform multiple operations, this language is intended to broadly cover a variety of processor architectures and environments. For example, unless explicitly claimed otherwise (e.g., via the use of “first processor” and “second processor” or other language that differentiates processors in the claims), this language is intended to cover a single processor performing or being configured to perform all of the operations, a group of processors collectively performing or being configured to perform all of the operations, a first processor performing or being configured to perform a first operation and a second processor performing or being configured to perform a second operation, or any combination of processors performing or being configured to perform the operations. For example, when a claim has the form “one or more processors configured to: perform X; perform Y; and perform Z,” that claim should be interpreted to mean “one or more processors configured to perform X; one or more (possibly different) processors configured to perform Y; and one or more (also possibly different) processors configured to perform Z.”

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”).

What is claimed is:

1. A method for providing thermal management of a three-dimensional (3D) integrated circuit, the method comprising:
changing a shape, an alignment, or a configuration of a four-dimensional (4D)-printed thermally adaptive structure in response to a thermal profile and workload data associated with the 3D integrated circuit;
receiving real-time sensor data associated with the 3D integrated circuit;
adjusting thermal pathways of the 3D integrated circuit using cooling elements, the 4D-printed thermally adaptive structure, and thermal routing layers; and
redistributing heat in the 3D integrated circuit in real-time based on the real-time sensor data.

2. The method of claim 1, further comprising:
processing the real-time sensor data and the workload data, with a machine learning model, to generate predicted thermal profiles; and
reconfiguring the thermal pathways and adapting the 4D-printed thermally adaptive structure based on the predicted thermal profiles.

3. The method of claim 2, further comprising:
updating a thermal management strategy for the 3D integrated circuit based on the predicted thermal profiles.

4. The method of claim 1, wherein the 4D-printed thermally adaptive structure includes one of a microfluidic channel, a thermally conductive fin, or an expandable layer.

5. The method of claim 1, wherein the 4D-printed thermally adaptive structure evolves with usage patterns and aging associated with the 3D integrated circuit.

6. The method of claim 1, further comprising:
enhancing the adjustment to the thermal pathways of the 3D integrated circuit by adapting the 4D-printed thermally adaptive structure to improve heat flow.

7. The method of claim 1, further comprising:
directing thermal dissipation to one or more of a logic core layer, a memory layer, or a power management layer of the 3D integrated circuit.

8. A thermal management system for a three-dimensional (3D) integrated circuit, the thermal management system comprising:
a four-dimensional (4D)-printed thermally adaptive structure configured to change a shape, an alignment, or a configuration in response to a thermal profile and workload data associated with the 3D integrated circuit;
one or more sensors configured to provide real-time sensor data associated with the 3D integrated circuit; and
a controller configured to:
adjust thermal pathways of the 3D integrated circuit using cooling elements, the 4D-printed thermally adaptive structure, and thermal routing layers, and
redistribute heat in the 3D integrated circuit in real-time based on the real-time sensor data.

9. The thermal management system of claim 8, wherein the controller is further configured to:
process the real-time sensor data and the workload data, with a machine learning model, to generate predicted thermal profiles; and
reconfigure the thermal pathways and adapt the 4D-printed thermally adaptive structure based on the predicted thermal profiles.

10. The thermal management system of claim 9, wherein the controller is further configured to:
update a thermal management strategy for the 3D integrated circuit based on the predicted thermal profiles.

11. The thermal management system of claim 9, wherein the machine learning model is trained on a dataset of thermal profiles and workload patterns.

12. The thermal management system of claim 8, wherein the 4D-printed thermally adaptive structure includes one of a microfluidic channel, a thermally conductive fin, or an expandable layer.

13. The thermal management system of claim 8, wherein the 4D-printed thermally adaptive structure evolves with usage patterns and aging associated with the 3D integrated circuit.

14. The thermal management system of claim 8, wherein the 4D-printed thermally adaptive structure is further configured to:
identify a layer of the 3D integrated circuit experiencing thermal stress; and
focus heat dissipation on the layer experiencing thermal stress.

15. The thermal management system of claim 8, wherein the 4D-printed thermally adaptive structure is further configured to:
detect damage to the 4D-printed thermally adaptive structure; and
repair the damage.

16. The thermal management system of claim 8, wherein the 4D-printed thermally adaptive structure is further configured to:
enhance the adjustment to the thermal pathways of the 3D integrated circuit by adapting to improve heat flow.

17. The thermal management system of claim 8, wherein the 3D integrated circuit includes a logic core layer, a memory layer, and a power management layer, and the controller is further configured to:
direct thermal dissipation to one or more of the logic core layer, the memory layer, or the power management layer.

18. The thermal management system of claim 8, wherein the 4D-printed thermally adaptive structure is fabricated from a shape-memory polymer or a phase-change material that reacts to an environmental trigger.

19. The thermal management system of claim 8, wherein the one or more sensors are distributed across a logic core layer, a memory layer, and a power management layer of the 3D integrated circuit.

20. A three-dimensional (3D) integrated circuit, comprising:
a logic core layer;
a memory layer;
a power management layer; and
a thermal management system that includes:
a four-dimensional (4D)-printed thermally adaptive structure configured to change a shape, an alignment, or a configuration in response to a thermal profile and workload data associated with the 3D integrated circuit;
one or more sensors configured to provide real-time sensor data associated with the 3D integrated circuit; and
a controller configured to adjust thermal pathways of the 3D integrated circuit using cooling elements, the 4D-printed thermally adaptive structure, and thermal routing layers, and redistribute heat in the 3D integrated circuit in real-time based on the real-time sensor data.
